(19) United States
(12) Patent Application Publication
(10) Pub. No.: US 2005/0095776 A1
(43) Pub. Date: May 5, 2005

(54) Semiconductor manufacturing apparatus, semiconductor manufacturing method and wafer stage

(75) Inventor: Hirohisa Usuami, Tokyo (JP)

Correspondence Address: Stanley P. Fisher;Reed Smith LLP, Suite 1400, 3110 Fairview Park Drive, Falls Church, VA, 22042-4503, US

(73) Assignee: Trecenti Technologies, Inc.

(21) Appl. No.: 10/975,540

(22) Filed: Oct. 29, 2004

(30) Foreign Application Priority Data
Oct. 29, 2003 (JP) JP2003-368402

(51) Int. Cl. H01L 21/8238

(52) U.S. Cl. 438/232

(57) ABSTRACT

A stage main body of a wafer stage having electrostatic chuck function is sectioned into plural chucking areas with partition members. Each chucking area includes electrodes capable of changing an applied voltage, a helium supply pipe and a fluorescent thermometer. The distribution of the temperature of a wafer is grasped at real time by measuring the temperature of the wafer corresponding to the plural chucking areas. A local temperature correction for the wafer is carried out by adjusting the electrostatic chucking force in the chucking area corresponding to a necessary temperature corrective area. By achieving the temperature control within the wafer surface in this way, the equality in wafer processing, which is affected by the wafer temperature, is secured thereby eliminating the inequality in processing accuracy of the wafer processing within a wafer surface.

### CROSS-REFERENCE TO RELATED APPLICATION

The present application claims priority from Japanese Patent Application No. JP 2003-368402 filed on Oct. 29, 2003, the content of which is hereby incorporated by reference into this application.

### TECHNICAL FIELD OF THE INVENTION

The present invention relates to an improvement technology for uniformity of a wafer surface upon manufacturing of a semiconductor device and more particularly to a technology which is effective when it is adopted for wafer processing in the conditions that the wafer is electrostatically chucked by a vacuum system.

### BACKGROUND OF THE INVENTION

The technologies, which will be described, have been considered by the present inventor when the present invention is completed and the outline thereof will be explained briefly. When manufacturing a semiconductor device, various kinds of processings are carried out on a wafer, for example, a fine pattern lithography. At the time of this processing, the wafer is held securely on a wafer stage for deflecting from its proper position.

As such a wafer holding means, electrostatic chuck method has been well known, this method being capable of holding the wafer even in vacuum system. This electrostatic chuck type wafer holding method has been generally employed for dry etching apparatus such as plasma etching unit as well as a thin film forming apparatus such as CVD unit.

Recently, in the manufacturing field of the semiconductor device, enlargement of the diameter of the wafer (+300 mm) which serves as a substrate for the semiconductor device, increased accuracy in processing (±10 nm), intensified fineness (less than 0.13 μm) and the like have been demanded and accompanied by these trends, inequality in processing accuracy within the wafer surface has been taken up as a serious problem. For example, a problem that the etching accuracy differs between the central area and the outer peripheral area of the wafer surface has been pointed out.

As a solution method about the inequality in processing accuracy between the central area and the outer peripheral area of the wafer surface, for example, Helium gas is fed between a wafer and a wafer stage for holding the wafer by chucking electrostatically so as to raise heat conductivity and in order to reflect the temperature on the wafer stage upon the wafer, Helium gas is supplied to the central area and the outer peripheral area of the wafer stage from different systems so as to control the temperatures of the central area and the outer peripheral area of the wafer independently. This method has been adopted in a marketed apparatus.

Further, when holding the wafer on the wafer stage by chuck using an electrostatic chucking force, electricity is supplied to the central area and the outer peripheral area of the wafer stage from different systems and the chucking force of the wafer stage to the wafer is changed between the central area and the outer peripheral area of the surface so as to control heat conduction, thereby reflecting its temperature gradient upon the wafer. This method has been also adopted in another marketed apparatus.

As for a method of controlling the chucking force on the wafer, a method in which the electrode is divided to some areas in the form of rectangles or coaxially so as to control potential has been proposed as a method which achieves chuck of a warped wafer securely (see Japanese Patent Application Laid-Open Publication No. 6-204325), though it is not for controlling temperature within the surface of wafer. For example, a stronger electrostatic force is applied to the outer peripheral area of the wafer likely to detach from the wafer stage due to a large warp than the central area within the wafer surface, so as to increase the degree of the chuck of the wafer outer periphery to the wafer stage, so that the wafer can be held on the wafer stage in a flatter condition.

### SUMMARY OF THE INVENTION

The present inventor has found out a following problem in the above-described technology. That is, although it can be expected that the method of supplying Helium gas to the central area and the outer peripheral area of the wafer stage separately from different two systems provides a relatively preferable correspondence to a case where the inequality in processing accuracy within the wafer surface is generated coaxially, the inequality in actual processing accuracy within the surface often occurs locally within the wafer surface and this inequality within the surface generated non-coaxially cannot be met appropriately by the above-mentioned conventional method.

Similarly, even if the configuration to independently change an electrostatic force between the center side and outer peripheral side of the surface is adopted, it is not effective to the case where the assumed inequality within the lone has been generated coaxially but not sufficient to the case where the inequality has been generated non-coaxially.

Further, in the wafer temperature control of the conventional method, no wafer temperature at the time of wafer processing has been measured. The conventional wafer temperature control was carried out with a defective result such as processing accuracy after wafer processing employed as a direct index. That is, electrostatic chucking force, Helium gas supply and the like are controlled so as to achieve a necessary temperature control based on the defective result after wafer processing and with that condition, the wafer processing are executed based on the conditions, and the result is further confirmed so as to check the validity in electrostatic chucking force and Helium gas supply control.

For the reason, it takes a long time until an appropriate control condition is found out, so that a rapid countermeasure is difficult. Further, this conventional method is hardly capable of corresponding to sudden changes.

The present inventor has considered that the wafer temperature control can be achieved only by verifying a wafer temperature upon wafer processing at real time and that technological development at this point is necessary.

The inequality in processing accuracy within the surface can be caused from a property inherent of an apparatus for use. In such a case, the generated inequality within the surface differs depending on each apparatus and cannot be treated with such a conventional measure which depends on a preliminarily fixed corresponding means such as the one separately oriented for the central area and the outer peripheral area of the wafer surface.

An object of the present invention is to improve the equality in processing accuracy within the wafer surface by executing the temperature control of a wafer in conditions that the wafer is electrostatically chucked on a wafer stage.

The aforementioned and other objects and novel features of the present invention will be made evident from a description of this specification and the accompanying drawings.

A typical one of the aspects of the invention disclosed in this application will be briefly described below.

The present invention provides a semiconductor manufacturing apparatus capable of solving an inequality in wafer processing within a wafer surface by changing an electrostatic chucking force in each of plural chucking areas provided on a wafer stage.

The advantages achieved by the typical ones of the inventions disclosed in this application will be briefly described as follows.

Namely, the equality in wafer processing within a wafer surface can be improved.

### BRIEF DESCRIPTIONS OF THE DRAWINGS

FIG. 1A is an explanatory diagram showing schematically plural chucking areas in a wafer stage according to an embodiment of the present invention;

FIG. 1B is an explanatory diagram showing schematically a condition in which the chucking area is further divided to smaller chucking areas;

FIG. 2 is an explanatory diagram showing schematically the cross section of the wafer stage according to an embodiment of the present invention;

FIG. 3 is a flow chart showing the procedure for temperature distribution correction within a wafer surface;

FIG. 4 is a flow chart showing the correction procedure of etching rate distribution within the wafer surface;

FIG. 5 is a flow chart showing the distribution correcting procedure for processing dimensions within the wafer surface; and

FIG. 6 is a flow chart showing the procedure of film thickness distribution correction within the wafer surface.

### DESCRIPTION OF THE PREFERRED EMBODIMENTS

Hereinafter, the preferred embodiments of the present invention will be described in detail with reference to the accompanying drawings. In all diagrams for explaining the embodiments, like reference numerals are attached to the same components and a repeated description thereof may be omitted.

### First Embodiment

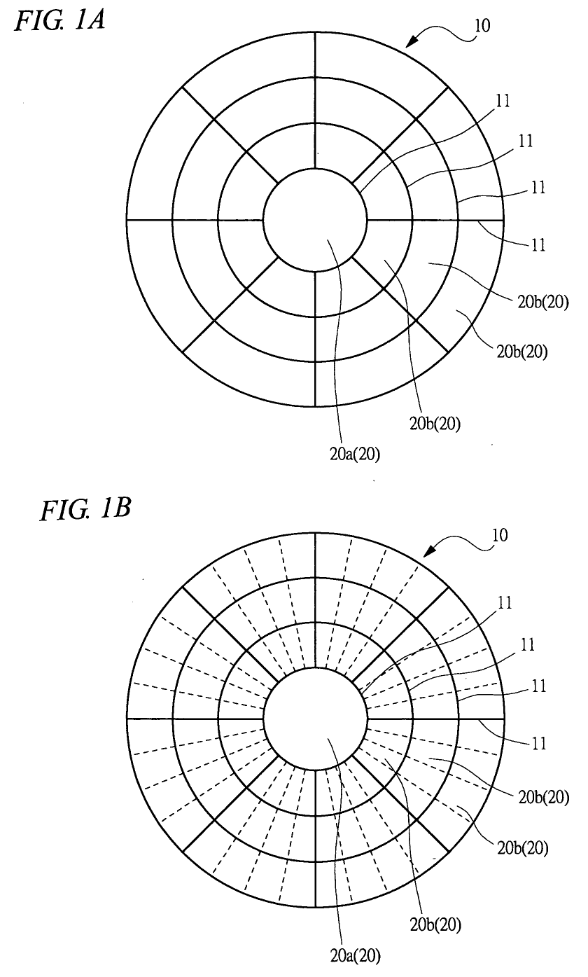

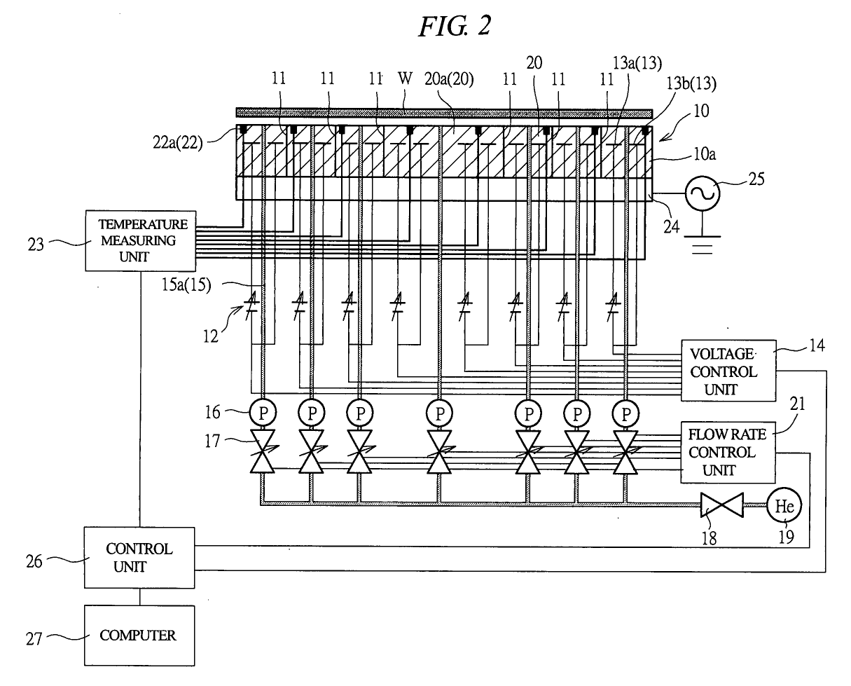

According to this embodiment, a wafer stage of the present invention will be described. FIG. 1A is a plan view showing schematically the condition of plural chucking areas on the wafer stage. FIG. 1B is an explanatory diagram showing schematically a condition in which the chucking area is further divided to smaller chucking areas. FIG. 2 is an explanatory diagram of the cross section showing schematically the structure of the wafer stage.

For this embodiment, a wafer stage employing electrostatic chucking force for use in a vacuum chamber for generating plasma such as a dry etching will be exemplified.

A wafer stage 10 has a stage main body 10a formed in a substantially fat circular disk of insulating material such as ceramic in order to hold a wafer W on its top face as shown in FIGS. 1A and 2.

As shown in FIG. 2, the stage main body 10a is divided into a plurality of sections by partition members 11 formed of insulating member. In FIG. 1A for example, the partition members 11 are disposed coaxially and radiantly with respect to the center of the wafer stage 10. The stage main body 10a of the wafer stage 10 is partitioned to a plurality of sections or chucking areas 20 by the partition members 11.

In a case shown in FIG. 1A, a circular chucking area 20a (20) is provided in the center of the wafer stage 10 and chucking areas 20b (20) having semi-ring shape are provided around the circular chucking area 20a (20). However, the division of the wafer stage 10 is not restricted to the case shown in FIG. 1A but it is permissible to set it up arbitrarily. For example, the wafer stage may be formed in grid pattern such that a plurality of partition members 11 run in perpendicular directions. Further, individual sections may be formed in different sizes or in different shapes without being formed in the same size or the same shape.

As the sections are formed in smaller sizes, namely, the chucking areas 20 are formed in a smaller size and in a larger quantity, wafer temperature control which the present invention aims at can be executed more precisely.

As shown in FIG. 2, a pair of electrodes 13a, 13b, which are connected to a power supply 12 capable of changing the voltage, are provided in each of the sectioned chucking areas 20 as an electrostatic chucking means 13.

Electrodes 13a, 13b are embedded in the stage main body 10a. As shown in FIG. 2, each power supply 12 is connected to a voltage control unit 14 so that the voltage can be changed independently according to an instruction from the voltage control unit 14. By changing the voltage of each of the plural chucking areas 20 independently, the degree of chuck of the wafer W can be changed by the unit of the chucking area 20.

A heat medium supply means 15 is provided for temperature adjustment of the wafer W to be electrostatically chucked on each of the chucking areas 20, so that inert gas as a heat medium can be supplied between the wafer stage 10 and the rear surface of a wafer W to be electrostatically chucked on the top surface of the wafer stage. In a case shown in FIG. 2, Helium (He) which is inert gas is used as refrigerant and a helium supply pipe 15a (15), whose supply port is open on the top surface of the stage main body 10a, is provided in each of the chucking areas 20.

Helium supplied to each chucking area 20 through the supply pipe 15a is emitted to the rear face of the wafer W through the supply port and dissipated around along gaps between the wafer W and the chucking areas 20. When helium flows along the rear surface of the wafer W heat of the wafer W is removed so that the wafer W can be cooled.

Grooves, which lead to the supply port, are provided in the top face of each chucking area 20, that is, the top face of the stage main body 10a, so that helium discharged from the supply port can make uniform contact with the rear face of the wafer W. Consequently, equality in cooling can be secured for each chucking area 20.

As shown in FIG. 2, the supply pipe 15a is connected to a gas supply source 19 such as a gas cylinder for helium through a pressure gauge 16, a flow meter 17 and a valve 18. The flow meter 17 is connected to a flow amount control unit 21 so that the flow rate can be controlled independently according to an instruction from the flow rate control unit 21. By changing the flow rate for each of the plurality of chucking areas 20 independently, the temperature of each chucking area of the wafer W can be changed.

Further, each of the chucking areas 20 is provided with a temperature measuring means 22 and thus, the temperature in an area of the wafer W opposing each chucking area 20 can be measured. By measuring the temperature of the wafer W at areas opposing such plural chucking areas, the wafer temperature can be grasped as not an average temperature of the wafer W based on temperature measurements at several points but as a temperature distribution in the wafer W areas corresponding to the plural chucking areas 20.

By providing the wafer stage 10 with the temperature measuring means 22, the temperature of the wafer W during wafer processing can be grasped at real time different from the conventional technology.

Because the temperature measuring means 22 is provided at each of the plural chucking areas 20, the temperature of the wafer W during wafer processing is not grasped as an average temperature of wafers but can be grasped as the temperature distribution of the respective areas corresponding to individual chucking areas, so that precise wafer temperature control can be achieved different from the conventional technology.

That is, as shown in FIG. 2, a thermometer is provided as the temperature measuring means 22 within each chucking area 20. This thermometer is capable of measuring the temperature of the rear face of the wafer W electrostatically chucked on the wafer stage 10 and this adopted thermometer is capable of measuring the temperature even in the conditions that the wafer W slightly floats over the top face of the stage main body 10a as well as that it keeps contact with the top face of the stage main body 10a.

As such a thermometer, in a case shown in FIG. 2, a fluorescent thermometer 22a (22) is adopted. Further, the temperature measuring means 22a constituted in the fluorescent thermometer 22a is connected to the temperature measuring unit 23 as shown in FIG. 2 so as to grasp the condition in the temperature distribution on the wafer W. The temperature measuring means is required to execute nothing but measuring the temperature of the wafer W even if the wafer is separate from the wafer stage and there is no problem if a temperature measuring means using an infrared ray sensor is adopted other than the fluorescent thermometer 22a.

Under the above-described structure, the temperature measuring means 22, provided on the stage main body 10a, aims at measuring not the temperature of the stage main body 10a but the temperature of the wafer W. Because with the above-described structure, the temperature measuring means 22 is provided opposing the rear face of the wafer W, even if plasma is employed for wafer treatment, a large influence of the plasma upon the temperature measurement can be avoided.

The stage main body 10a is provided on a lower electrode 24 constituted of parallel flat plates for generating plasma when a RF (radio frequency) power is applied between upper and lower electrodes as shown in FIG. 2. The lower electrode 24 is connected to a biased RF (radio frequency) power supply 25.

On the other hand, as shown in FIG. 2, the voltage control unit 14, the flow rate control unit 21 and the temperature measuring unit 23 are connected to the control unit 26 and then connected to a computer 27 used as a host for control management.

Although the wafer stage has been described specifically based on the embodiments, the present invention is not restricted to such embodiments and needless to say, may be changed in various ways within a range not departing from the gist of the invention.

Although an example in which the plural chucking areas 20 provided on the wafer stage are sectioned with the partition members 11 for each chucking area 20 has been described above, there is no problem even if the structure includes no such partition member 11. For example, the structure shown in FIGS. 1A and 2 may exclude only the partition member 11.

The quantity of the electrostatic chucking means provided in each chucking area 20 sectioned by the partition member 11 is permitted to be plural. Further, the chucking area 20 sectioned by the partition member 11 may be divided into further small areas and such small areas may be provided with each electrostatic chucking means. For example, as shown in FIG. 1B, the chucking area 20 can be divided to plural parts as indicated with dotted lines. Although in a case indicted by FIG. 1B, the central circular chucking area 20a (20) is not divided, needless to say, the central circular area 20a (20) may be divided to small parts.

Using the wafer stage 10 having such a structure enables a precise wafer temperature control to be executed based on the temperature distribution of the wafer W electrostatically chucked. For example, as for the wafer temperature control, the wafer temperature can be changed during a treatment of the wafer W electrostatically chucked by the wafer stage 10.

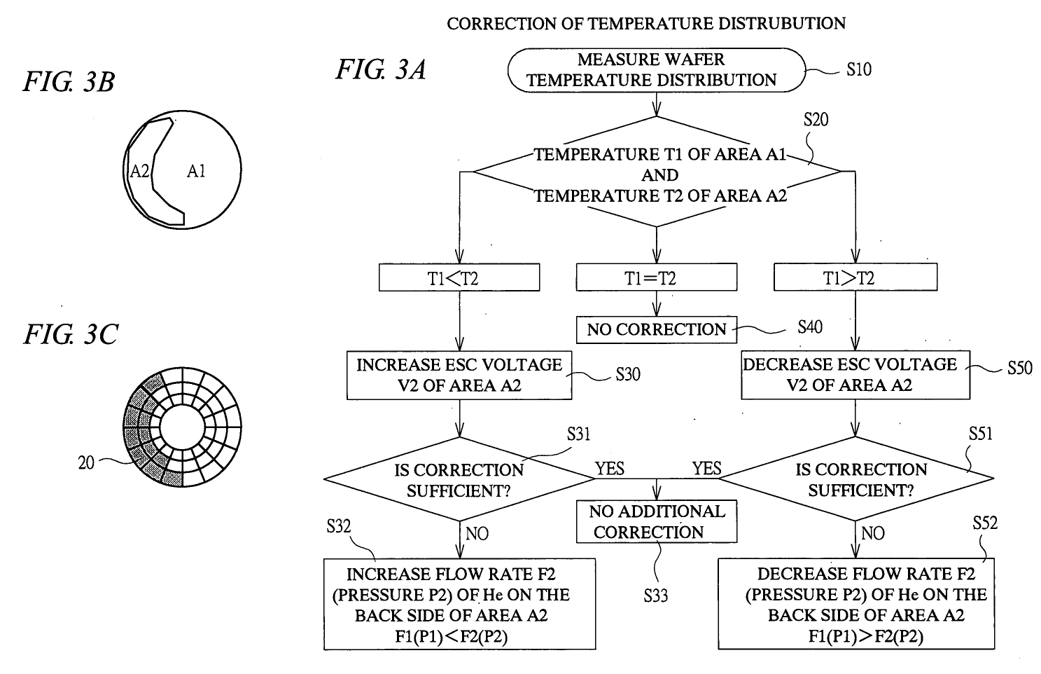

Such wafer temperature control is carried out by correcting the temperature of an area having an abnormal temperature, based on the temperature distribution of the wafer W grasped by the temperature measuring means 22. Next, the method for correcting the temperature will be described according to a flow chart indicating the procedure of the temperature correction shown in FIG. 3A.

A wafer W is electrostatically chucked on the wafer stage 10 as shown in FIG. 2. FIG. 2 represents a condition in which the wafer W is kept floated slightly apart from the stage main body 10a for convenience for explanation.

The wafer stage 10 is divided to plural chucking areas 20 as described previously and as shown in FIG. 3B in step S10, the temperature of the wafer W is measured by the fluorescent thermometer 22a provided in each chucking area 20. Measurement information is sent to the temperature measuring unit 23 and then, wafer temperature is grasped as the temperature distribution of the wafer W. That is, the wafer temperature is grasped as a temperature distribution based on the plural chucking areas 20 on the wafer stage 10.

A measurement result of the temperature distribution is sent to the computer 27 and its situation can be grasped by an operator through a monitor connected to the computer 27 or the like. For example, as shown in FIG. 3B, an area A1 at a temperature T1 and an area A2 at a temperature T2 are represented with different colors so that they can be distinguished. Further, as shown in FIG. 3C, the chucking area 20 corresponding to the areas A1, A2 is represented.

In the temperature distribution of the wafer W shown in FIGS. 3B and 3C, the temperature T1 and the temperature T2 are compared by the computer 27 as shown in step S20 and then, whether or not the temperature correction is necessary is determined.

For example, if as a result of comparison, the temperature T2 is higher than the temperature T1 (T1<T2), it is determined that the temperature correction is necessary and a corrective measure for lowering the temperature T2 on the side of the area A2 is automatically carried out based on a recipe set up on software of the computer 27.

As for the corrective measure, as indicated by step S30, electrostatic chucking force at plural chucking areas 20 (shaded area) corresponding to the area A2 is raised to increase the degree of chuck so that the wafer W is brought near the stage main body 10a and receives a strong cooling effect by helium supplied between the wafer W and the wafer stage 10.

That is, the voltage control unit 14 is instructed to raise the voltage of the chucking area 20 corresponding to the area A2 while maintaining the voltage of the chucking area 20 corresponding to the area A1 through the control unit 26 following a determination in step S30 based on an instruction from the computer 27. In the meantime, in FIG. 3A, such a voltage is expressed as electrostatic chuck (ESC) voltage to indicate clearly that that voltage is a voltage for electrostatic chuck control. This is the same in subsequent diagrams.

As a result, the area A2 of the wafer W is electrostatically chucked on the side of the stage main body 10a of the wafer stage 10 so as to lower the temperature T2. How the temperature is lowered is grasped at real time based on the measurement of temperature with the temperature measuring means 22 in the chucking area 20 corresponding to the area A2 and the temperature correction performed in step S30 is evaluated in step S31.

That is, in step S31, whether or not the correction performed in step S30 is sufficient is determined and whether a further temperature correction is necessary is determined. This determination is carried out based on comparison results of the temperatures T1, T2.

If in step S31, it is determined that the temperature T2 of the area A2 after temperature correction is higher than the temperature T1, it is determined that the correction is insufficient (NO) and the procedure proceeds to step S32, in which a next temperature correcting measure is taken.

As for such temperature correcting measure, the flow rate of helium is increased in conditions in which the electrostatic chuck condition executed in step S30 is maintained so as to intensify the cooling effect of helium. The computer 27 instructs to increase the flow rate of helium in the chucking area 20 corresponding to the area A2 through the control unit 26 so as to follow a determination of step S32 and to maintain the flow rate of helium in the chucking area 20 corresponding to the area A1, so as to ensure cooling such that the temperature T2 of the area A2 is substantially equal to the temperature T1.

On the other hand, if the temperature T2 is lowered sufficiently by the temperature corrective measure of changing the electrostatic chucking force in step S30 following a determination of step S31, it is determined that the correction is sufficient (YES) and it is determined that no additional correction is scheduled as shown in step S33 and then, the temperature correction is terminated.

If the temperature T1 is equal to the temperature T2 as a result of temperature comparison in step S20, it is determined that no correction is scheduled in step S40 because both the areas A1, A2 have a normal temperature.

As for the result of temperature comparison in step S20, if the temperature T2 is determined to be lower than the temperature T1 (T1>T2), the corrective measure for raising the temperature T2 on the side of the area A2 is automatically carried out based on a recipe set up on software of the computer 27 preliminarily.

As for the corrective measure, the electrostatic chucking force of the chucking area 20 corresponding to the area A2 is lowered as indicated in step S50 so as to keep the wafer W away from the stage main body 10a, thereby reducing influences of cooling effect of helium supplied between the wafer W and the wafer stage 10.

That is, the computer 27 instructs the voltage control unit 14 to lower the voltage of the chucking area 20 corresponding to the area A2 through the control unit 26 following a determination of step S50 so as to maintain the voltage of the chucking area 20 corresponding to the area A1.

As a result, the area A2 of the wafer W is departed from the stage main body 10a of the wafer stage 10 so that the temperature T2 is raised. How the temperature rises is grasped at real times based on the measurement of the temperature in the chucking area 20 corresponding to the area A2 and whether or not the correction executed sufficiently in step S50 is determined. That is, whether or not a further temperature correction is necessary is determined in step S51.

If it is determined that the temperature T2 in the area A2 after correction is lower than the temperature T1, it is determined that the correction is insufficient (NO) in step S51 and then, the procedure proceeds to step S52, in which a next temperature correction measure is taken.

As for such temperature corrective measure, with the electrostatic chuck condition achieve in step S50 maintained, the flow rate of helium is reduced so as to weaken the cooling effect of helium. The computer 27 instructs the control unit 26 to reduce the flow rate of helium to the chucking area 20 corresponding to the area A2 and maintain the flow rate of helium in the chucking area 20 corresponding to the area A1, so as to raise the temperature T2 of the area A2 to be substantially equal to the temperature T1.

On the other hand, if the temperature T2 is raised sufficiently by the temperature corrective measure of changing the electrostatic chucking force executed in step S50, it is determined that the correction is sufficient (YES) and it is determined that no additional correction is scheduled as indicated in step S33 and then, the temperature correction is terminated.

Although an example in which the flow rate of helium is controlled is indicated as the temperature corrective measure executed in steps S32 and S52 in the above description, it is permissible to control the pressure of helium instead. That is, it is permissible to adopt the pressure as an adjustment index instead of controlling the flow rate as an index. The index for determination can be replaced by considering that increase/decrease in flow rate corresponds to increase/decrease in pressure.

By using the wafer stage 10 having the above-described structure, the temperature control on a wafer electrostatically chucked by the wafer stage 10 can be carried out precisely by adjusting electrostatic chucking force and using the helium cooling effect at the same time corresponding to the wafer temperature distribution grasped at real time for each sectioned chucking area.

Although the precise wafer temperature control based on a wafer temperature distribution grasped at real time could not be carried out conventionally, it is greatly meaningful that the present invention has first attained this.

Such precise correction of the surface temperature is greatly affected on how finely the chucking area 20 in the wafer stage 10 can be set up. Thus, it can be said that the setting of the chucking area 20 which can be corrected is more effective for the surface temperature control for a wafer having a large diameter such as a φ300 mm wafer than a small area wafer which is difficult to set up finely.

### Second Embodiment

For this embodiment, an example in which a semiconductor device is manufactured using a dry etching unit having the wafer stage 10 described in the first embodiment will be described.

As the dry etching unit, for example, parallel flat plate type plasma etching unit can be assumed. As for the structure of that unit, the wafer stage 10 having the above-described structure for chucking a wafer electrostatically is provided within a vacuum chamber for generating plasma (not shown).

An upper electrode is provided in parallel to and opposing the lower electrode 24 on which the stage main body 10a of the wafer stage 10 is provided. Etching gas is supplied in between the upper electrode and the lower electrode and the supplied etching gas is formed to plasma between the upper and lower electrodes so as to dry-etch a wafer electrostatically chucked on the wafer stage 10.

In such a dry etching, inequality in processing accuracy within the wafer surface becomes problematic. The inequality in processing accuracy originates from a difference in etching rate and by controlling the etching rate within the surface, such inequality can be solved.

As described above, the wafer stage 10 has a plurality of the chucking areas 20 which measure a temperature distribution of the wafer at real time to control the temperature of the wafer W for each area thereof based on the result of the measurement. Therefore, by equalizing the difference in etching rate by control of the surface temperature of the wafer W, the inequality in etching accuracy within the surface can be eliminated.

That is, by grasping the inequality in etching accuracy within the surface as an inequality in etching rate within the surface and further grasping the inequality in etching rate within the surface as a difference in temperature within the surface of the wafer W, the difference in the temperature within the surface of the wafer W is adjusted so as to eliminate the inequality in etching rate within the surface by the procedure for the temperature correction of the wafer W described in the first embodiment.

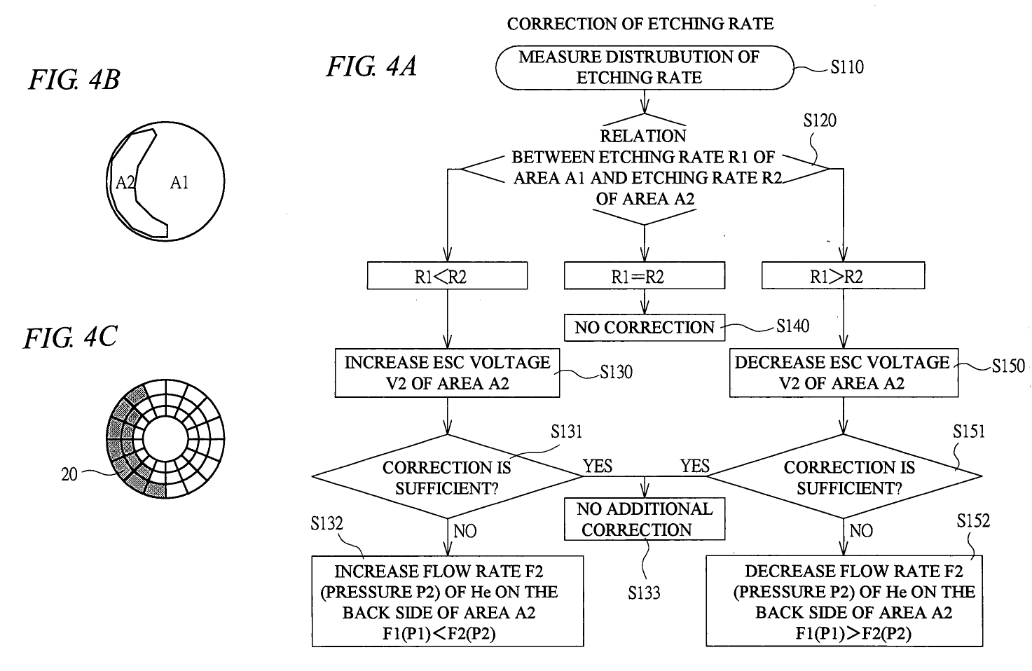

First, the wafer is processed with a dry etching unit having the above-described structure. The inequality in etching rate within the surface is recognized from the result of the treatment and in step S110 represented in the flow chart in FIG. 4A indicating the procedure for correcting the etching rate, that result is grasped as a distribution of the etching rate within the surface.

The result of the distribution of the etching rate within the surface can be recognized through a monitor as indicated in FIG. 4B. The area A1 of etching rate R1 and the area A2 of etching rate R2 can be recognized with different colors or the like. Additionally, as shown in FIG. 4C, the chucking area 20 corresponding to the areas A1 and A2 is grasped.

Next, in step S120, the etching rates of the areas A1 and A2 are compared. For example, it is assumed that the etching rate R1 is normal or the etching accuracy of the area A1 is normal while the etching accuracy of the area A2 is wrong.

If it is determined that the etching rate R2 is higher than the etching rate R1 (R2<R1) as a result of the comparison, a corrective measure for lowering the etching rate R2 of the area A2 is automatically carried out according to the recipe set up on software in the computer 27 preliminarily.

As the corrective measure, as indicated in step S130, the electrostatic chucking force of the chucking area 20 (shaded area) corresponding to the area A2 is raised so as to bring the wafer W near the stage main body 10a so that the wafer W is strongly affected by a cooling effect of Helium gas flowing between the wafer W and the wafer stage 10. Consequently, the wafer temperature of the area A2 is lowered.

If the wafer temperature of the area A2 becomes lowered, the etching rate R2 results in decreasing. That is, the computer 27 instructs the voltage control unit 14 to raise the voltage of the chucking area 20 corresponding to the area A2 and maintain the voltage of the chucking area 20 corresponding to the area A1 through the control unit 26 so as to follow the above-mentioned determination of step S130.

The degree of chuck increases due to the control of the electrostatic chucking force, so that the area A2 of the wafer W is electrostatically chucked by the side of the stage main body 10a of the wafer stage 10 and the wafer temperature decreases thereby slowing down the etching rate R2. The wafer treatment is carried out under such a condition and to what extent the etching rate slows down is grasped based on the result of measurement of the etching accuracy in the chucking area 20 corresponding to the area A2. The correction of the etching rate executed in step S130 is evaluated in step S131.

That is, in step S131, whether or not the correction executed in step S130 is sufficient is evaluated and whether or not a further correction of the etching rate is necessary is determined. That is, whether or not a further temperature correction is necessary is determined.

If in step S131, the etching rate R2 of the area A2 after correction is higher than the etching rate R1, it is determined that the correction is insufficient (NO) and the procedure proceeds to step S132, in which a further correction measure of the etching rate is taken.

As for the corrective measure of the etching rate, with the electrostatic chuck condition carried out in step S130 maintained, the flow rate of helium (or pressure) is increased so as to intensify the cooling effect of helium. Consequently, the wafer temperature of the area A2 is further decreased whereby slowing down the etching rate R2.

The computer 27 issues an instruction to increase the flow rate (or pressure) of helium in the chucking area 20 corresponding to the area A2 through the control unit 26 while maintaining the flow rate (or pressure) of helium in the chucking area 20 corresponding to the area A1, so as to decrease the temperature T2 of the area A2 so that the etching rate R2 becomes substantially the same as the etching rate R1.

On the other hand, the temperature T2 can be lowered sufficiently by the temperature corrective measure by changing the electrostatic chucking force executed in step S130. If the etching rate R2 becomes the etching rate R1 which is a normal one, it is determined that the correction is sufficient (YES) and that no additional correction is necessary in step S133 and then, the correction of the etching rate is terminated.

As for the result of the comparison of the etching rates in step S120, if the etching rate R1 is equal to the etching rate R2 (R1=R2), it is determined that no correction is necessary is determined in step S140, because both the areas A1 and A2 have a normal etching rate.

As for the result of the comparison in step S120, if it is determined that the etching rate R2 is lower than the etching rate R1 (R1>R2), a corrective measure for increasing the etching rate R2 on the side of the area A2 is automatically carried out based on the recipe set up on software of the computer 27 preliminarily.

As the corrective measure, as indicated in step S150, the electrostatic chucking force in the chucking area 20 corresponding to the area A2 is decreased so as to bring the wafer W apart from the stage main body 10a. Consequently, the etching rate R2 increases while reducing the cooling effect of helium flowing between the wafer W and the wafer stage 10.

That is, the computer 27 instructs the voltage control unit 14 to decrease the voltage of the chucking area 20 corresponding to the area A2 while maintaining the voltage of the chucking area 20 corresponding to the area A1, through the control unit 26 following a determination in step S150.

As a result, the area A2 of the wafer W is departed from the stage main body 10a of the wafer stage 10, so that the temperature T2 increases and the etching rate R2 increases. To what extent the etching rate is increased is grasped based on a result of the measurement of the etching rate in the chucking area 20 corresponding to the area A2 and at the same time, whether or not the correction executed in step S150 is sufficient is determined. That is, whether or not a further correction of the etching rate is necessary is determined in step S151.

If the etching rate R2 of the area A2 after correction is lower than the etching rate R1 in step S151, it is determined that the correction is insufficient (NO) and the procedures proceeds to step S151, in which a next etching rate corrective measure is taken.

As for such a rate corrective measure, with the electrostatic chuck condition executed in step S150 maintained, the flow rate (or pressure) of helium is reduced so as to weaken the cooling effect of helium. The computer 27 issues an instruction to decrease the flow rate (or pressure) of helium in the chucking area 20 corresponding to the area A2 while maintaining the flow rate (or pressure) of helium in the chucking area 20 corresponding to the area A1 through the control unit 26 following a determination in step S152, so as to adjust the temperature T2 of the area A2 so that the etching rate R2 becomes substantially the same as the etching rate R1.

On the other hand, if it is determined that the etching rate R2 increases sufficiently through the etching rate corrective measure by changing the electrostatic chucking force executed in step S150 in step S151, it is determined that the correction is sufficient (YES) and that no additional correction is necessary as indicated in step S133 and then, the correction of the etching rate is terminated.

### Third Embodiment

For this embodiment, a method for solving the inequality in processing dimension within the surface accompanied by such dry etching by controlling the temperature within the surface of the wafer using the wafer stage 10 will be described. The inequality in processing accuracy within the wafer surface can be grasped as a difference in etching rate (difference in deposition amount for side wall protecting film) and such a difference in etching rate can be corrected by controlling the temperature within the wafer surface as described in the previous embodiment.

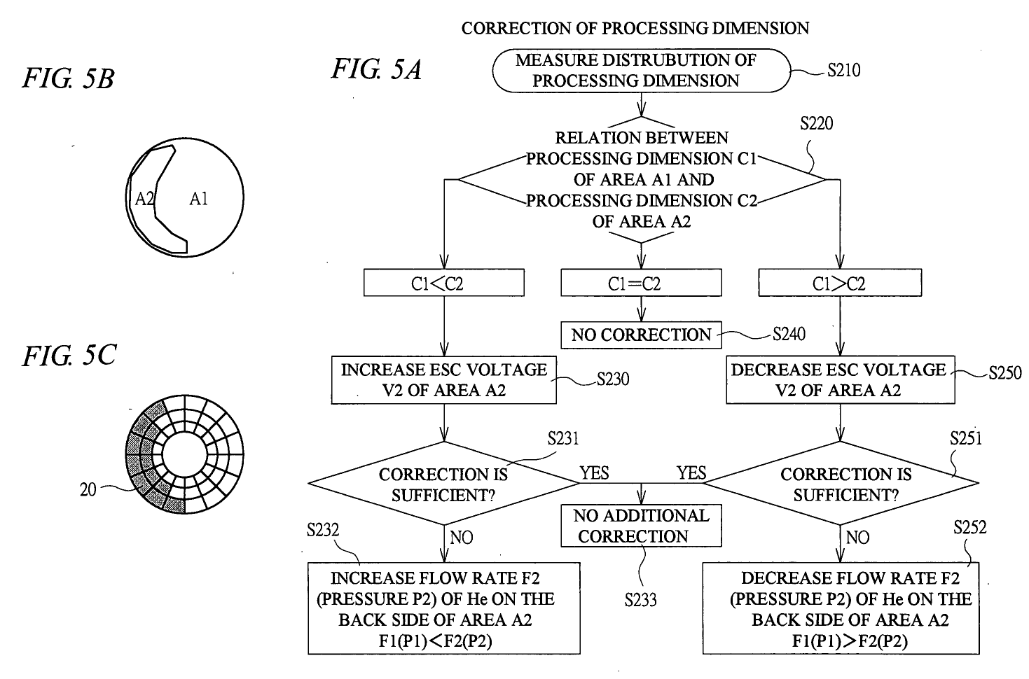

The wafer is processed with a dry etching apparatus having the above-described structure. From that processing result, a distribution of processing dimension within the surface is measured in step S210 as indicated in FIG. 5A. Consequently, assume that two areas, area A1 and area A2, exist separately as shown in FIG. 5B. Such a distribution of the processing dimension within the surface can be recognized through a monitor also. At the same time, as shown in FIG. 5C, the chucking areas 20 corresponding to the areas A1, A2 are represented.

Next, in step S220, the processing dimensions C1, C2 of the areas A1, A2 are compared. As an example, with the processing dimension C1 assumed to be normal, it is considered that the processing accuracy of the area A1 is poor although the processing accuracy of the area A1 is excellent.

As a result of comparison, it is considered that the area A2 is processed more excessively than the area A1. That is, if it is determined that the processing dimension C2 is larger than the processing dimension C1 (C1<C2), a corrective measure of reducing the processing dimension C2 of the area A2 is automatically taken according to a recipe set up on software of the computer 27 preliminarily.

As the corrective measure, as indicated in step S230, the electrostatic chucking force of the chucking area 20 (shaded area) corresponding to the area A2 is raised so as to bring the wafer W nearer the stage main body 10a, so that the wafer W receives a cooling effect more strongly by helium flowing between the wafer W and the wafer stage 10. Consequently, the wafer temperature in the area A2 decreases thereby the etching rate being decreased.

That is, the computer 27 instructs the voltage control unit 14 to decrease the voltage of the chucking area 20 corresponding to the area A2 while maintaining the voltage of the chucking area 20 corresponding to the area A1 through the control unit 26 following a determination of step S230.

As a result, the area A2 of the wafer W is electrostatically chucked by the stage main body 10a of the wafer stage 10, so that the wafer temperature is reduced and consequently the etching rate is decelerated thereby the processing dimension C2 being decreased. To what extent the processing dimension is improved is grasped based on the result of the measurement of the processing dimension in the chucking area 20 corresponding to the area A2 and the correction of the processing dimension executed in step S230 is evaluated in step S231.

That is, in step S231, whether or not the correction executed in step S230 is sufficient is evaluated and then whether or not a further correction of the processing dimension is necessary is determined. Namely, whether or not a further temperature correction is necessary is determined.

In step S231, if the processing dimension C2 in the area A2 after the correction is larger than the processing dimension C1, it is determined that no correction is sufficient (NO) and then, the procedure proceeds to step S232, in which a further corrective measure for the processing dimension is taken.

As for the corrective measure for the processing dimension, with the electrostatic chuck condition achieved in step S230 maintained, the flow rate (or pressure) of helium is increased so as to intensify the cooling effect of helium. Consequently, the wafer temperature in the area A2 is decreased further, so that the etching rate is decreased thereby the processing dimension being decreased.

The computer 27 dispatches an instruction to increase the flow rate (or pressure) of helium in the chucking area 20 corresponding to the area A2 while maintaining the flow rate of helium in the chucking area 20 corresponding to the area A1 through the control unit 26 following a determination in step S232. Consequently, the temperature T2 of the area A2 is decreased so that the processing dimension C2 becomes substantially the same as the processing dimension C1.

On the other hand, as a result of determination in step S231, the processing dimension C2 can be reduced sufficiently by processing dimension corrective measure by the change of the electrostatic chucking force executed in step S230 and if that processing dimension becomes normal processing dimension C1, it is determined that the correction is sufficient (YES) and then that no additional correction is necessary in step 233. Then, the correction of the processing dimension is terminated.

If the result of comparison of the processing dimensions in step S220 shows that the processing dimensions C1 and C2 are equal, it is determined that no correction is necessary, in step S240, because both the areas A1, A2 are normal.

As for the result of the comparison in step S220, if it is determined that the processing dimension C2 is far smaller than the processing dimension C1, that is, it is determined that C1>C2, a corrective measure for enlarging the processing dimension C2 in the area A2 is automatically executed according to a recipe set up on software of the computer 27 preliminarily.

As the corrective measure, as indicated in step S250, the electrostatic chucking force of the chucking area 20 corresponding to the area A2 is lowered so as to bring the wafer W apart from the stage main body 10a, thereby reducing an influence of the cooling effect of Helium gas flowing between the wafer W and the wafer stage 10. As a result, the etching rate increases thereby the processing dimension C2 being reduced.

That is, the computer 27 instructs the voltage control unit 14 to decrease the voltage of the chucking area 20 corresponding to the area A2 while maintaining the voltage of the chucking area 20 corresponding to the area A1 through the control unit 26 following a determination in step S250.

As a result, the area A2 of the wafer W is departed from the stage main body 10a of the wafer stage 10 so as to raise the wafer temperature, so that the etching rate increases thereby the processing dimension C2 being increased. To what extent that processing dimension is improved is grasped based on the result of measurement of the processing dimension accuracy in the chucking area 20 corresponding to the area A2 and at the same time, whether or not the correction executed in step S250 is sufficient is determined. That is, whether or not a further correction of the processing dimension is necessary is determined in step S251.

In step S251, if the processing dimension C2 of the area A2 after the correction is smaller than the processing dimension C1, it is determined that the correction is insufficient (NO) and the procedure proceeds to step S252, in which a next processing dimension corrective measure is taken.

As for the processing dimension corrective measure, with the electrostatic chuck condition achieved in step S250 maintained, the flow rate (or pressure) of helium is decreased so as to weaken the cooling effect of helium. The computer 27 instructs to reduce the flow rate (or pressure) of helium in the chucking area 20 corresponding to the area A2 while maintaining the flow rate (pressure) of helium in the chucking area 20 corresponding to the area A1 through the control unit 26 following a determination in step S252. Consequently, the temperature T2 of the area A2 is raised, so that the processing dimension C2 becomes substantially the same as the processing dimension C1.

On the other hand, if as a result of determination in step S251, the processing dimension C2 is increased sufficiently by the corrective measure by change of the electrostatic chucking force executed in step S250, it is determined that the correction is sufficient (YES) and then that no additional correction is necessary in step S233 and then, the temperature correction is terminated.

### Fourth Embodiment

In this embodiment, a manufacturing method of a semiconductor device comprising a step of etching processing without over-etching at thin areas in film thickness by controlling the temperature within the wafer surface when dry-etching a unprocessed film having uneven film thickness formed in a previous step will be described below.

First, the thickness of the thin film formed on a wafer in upstream steps is checked. The distribution of film thickness of the unprocessed film to be removed by dry-etching, formed on the wafer is confirmed using film thickness measuring means.

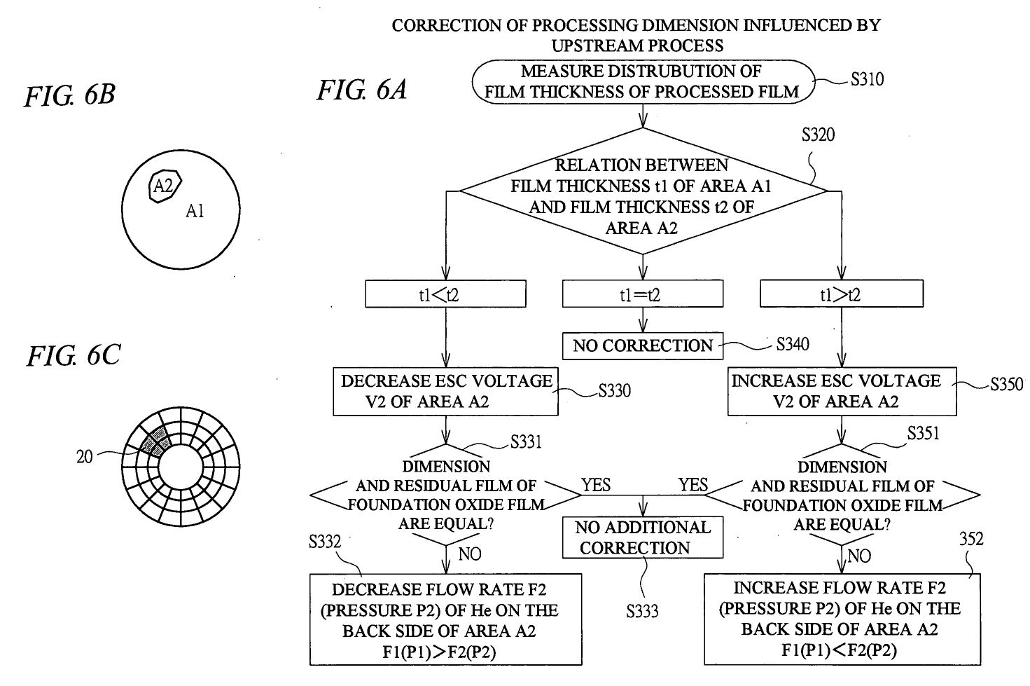

That is, as shown in a flow chart of FIG. 6A, the distribution of the film thickness of the unprocessed film is measured in step S310. As a result, it is assumed that the areas A1, A2 are represented as shown in FIG. 6B. As shown in FIG. 6B, part of the wafer surface is different form the surrounding in terms of film thickness.

In step S320, the areas A1 and A2 are compared in terms of film thickness. If the film thickness t1 of the area A1 is larger than the film thickness t2 of the area A2, the film thickness of the areas A1 and A2 can be equalized by making the etching rate for the area A2 faster than the etching rate for the area A1 upon dry-etching.

If the film thickness t1 is thinner than the film thickness t2, as a corrective measure, the electrostatic chucking force in the chucking area 20 corresponding to the area A2 is lowered so as to bring the wafer W apart from the stage main body 10a in step S330, so that the wafer W becomes unlikely to obtain a cooling effect by helium flowing between the wafer W and the wafer stage 10. Consequently, the wafer temperature in the area A2 rises so as to increase the etching rate, thereby the etching amount in the area A2 being increased.

That is, the computer 27 instructs the voltage control unit 14 to decrease the voltage of the chucking area 20 corresponding to the area A2 while maintaining the voltage of the chucking area 20 corresponding to the area A through the control unit 26 following a determination in step S330.

As a result, the degree of chuck in the area A2 of the wafer W decreases so that the wafer W is brought apart from the stage main body 10a of the wafer stage 10, thereby the wafer temperature being increased. Consequently, the etching amount increases by the same amount as the etching rate increases so that the area A1 is etched more than the area A2.

To what extent the etching amount is increased is grasped based on the result of measurement of the film thickness corresponding to the area A2 and the correction executed in step S330 is evaluated in step S331.

That is, in step S331, whether or not the correction executed in step S330 is sufficient is determined. Whether or not the film thickness and the residual film of foundation oxide film in the area A2 are equal to those in the area A1 is determined and whether or not a further correction is necessary is determined. That is, whether or not a further correction of temperature is necessary is determined.

If no sufficient etching amount is secured in the area A2 after the correction and it is determined that the correction is not sufficient (NO), the procedure proceeds to step S332, in which a further corrective measure is taken.

As for such a corrective measure, with the electrostatic chuck condition achieved in step S330 maintained, the flow rate (or pressure) of helium is lowered so as to restrict the cooling effect of helium, thereby the wafer temperature in the area A2 being decreased further. Consequently, the etching amount in the area A2 is increased.

The computer 27 issues an instruction to reduce the flow rate (or pressure) of helium in the chucking area 20 corresponding to the area A2 while maintaining the flow rate (or pressure) of helium in the chucking area 20 corresponding to the area A1 through the control unit 26 following a determination in step S332. Consequently, the results of dry-etching processing in the areas A2 and A1 become substantially the same.

On the other hand, if it is determined that the temperature can be raised sufficiently by the temperature corrective measure of changing the electrostatic chucking force executed in step S330 and that the correction is sufficient (YES) in step S331, it is determined that no additional correction is necessary in step S333 and the correction of the etching rate is terminated.

Further, as for the result of comparison of the film thickness in step S320, if the film thickness t1 is equal to the film thickness t2, it is not necessary to provide the different etching amounts between the areas A1 and A2. Thus, it is determined that no correction is necessary in step S340.

As for the result of the comparison of film thickness in step S320, if t2 is smaller than t1 (t1>t2), a corrective measure for reducing the etching amount in the area A2 is automatically executed according to a recipe set up on software of the computer 27 preliminarily.

As for a corrective measure, the electrostatic chucking force in the chucking area 20 corresponding to the area A2 is increased so as to bring the wafer W nearer the stage main body 10a, so that the wafer W is caused to be strongly influenced by the cooling effect of helium flowing between the wafer W and the wafer stage 10. Consequently, the etching rate is decreased.

That is, the computer 27 instructs the voltage control unit 14 to increase the voltage of the chucking area 20 corresponding to the area A2 while maintaining the voltage of the chucking area 20 corresponding to the area A1 through the control unit 26 following a determination in step S350.

As a result, the area A2 of the wafer W is brought near the stage main body 10a of the wafer stage 10, so that the temperature decreases and then, the etching rate decreases thereby the etching amount being reduced. To what extent the etching amount is suppressed is grasped based on the result of measurement of the film thickness in the chucking area 20 corresponding to the area A2 and then whether or not the correction executed in step S350 is sufficient is determined. That is, whether or not a further correction is necessary is determined in step S351.

In step S351, if it is determined that the correction is insufficient (NO), the procedure proceeds to step S352, in which a next corrective measure is taken.

As such a corrective measure, with the electrostatic chuck condition achieved in step S350 maintained, the flow rate (or pressure) of helium is increased so as to intensify the cooling effect of helium. The computer 27 dispatches an instruction to increase the flow rate (or pressure) of helium in the chucking area 20 corresponding to the area A2 while maintaining the flow rate (or pressure) of helium in the chucking area 20 corresponding to the area A1 through the control unit 26 following a determination in step S352. Consequently, the results of the dry-etching processing in the areas A1, A2 become substantially the same.

On the other hand, if it is determined that the etching amount is suppressed sufficiently by the corrective measure of changing the electrostatic force executed in step S350, it is determined that the correction is sufficient (YES) and that no additional correction is necessary in step S333 and then, the temperature correction is terminated.

If there is an inequality in film thickness of the processing film formed in a previous process as described above, an etching condition that no over-etching is progressed in a thin film area, that is, an etching condition which secures a large selectivity is demanded to be set up. However, according to the conventional art, such an etching condition cannot be set up easily.

However, by adjusting the temperature of a wafer partially with the wafer electrostatically chucked on the wafer stage 10 as described above, the extent of removal of unprocessed film by subsequent dry-etching processing can be made uniform regardless of the inequality in film thickness in the preceding step extremely easily.

Although the preferred embodiments of the present invention achieved by the present inventor have been described above, the present invention is not restricted to the above-mentioned embodiments but may be modified in various ways within a range not departing from the gist of the present invention.

Although in the above embodiments, a case for eliminating inequality in wafer processing within a wafer surface while controlling the wafer temperature precisely by applying the wafer stage of the present invention to a dry-etching unit has been described, it is permissible to adopt this wafer stage to a thin film forming unit such as CVD. The film thickness of deposited thin film can be increased partially by changing the electrostatic chuck amount on the wafer stage so as to control the wafer temperature, for example, raising the wafer temperature, thereby leading to solution of the inequality in the formed film within the wafer surface.

In case where plural different types of films are deposited, the etching process is changed in various ways for each film when etching such laminated different films. However, if the wafer temperature control method of the present invention is applied, the etching processing can be executed by changing the wafer temperature for each film while keeping the other etching conditions in the same ones.

Strictly speaking, the quantity of dope to polysilicone decreases at positions deeper from the surface of the polysilicone. Although the etching amount changes depending on the depth of the polysilicone, by using the wafer stage of the present invention, an influence of polysilicone upon the etching amount can be eliminated by changing the wafer temperature continuously while executing the etching processing.

Even if the etching amount increases so that etching is likely to narrow as it goes forward as the depth of the polysilicone intensifies, etching which is not narrowed as it goes forward can be attained by increasing the electrostatic chuck amount gradually to lower the wafer temperature continuously.

Because the wafer stage of the present invention enables a local temperature control at an arbitrary place of the wafer to be electrostatically chucked, even if equality in wafer processing cannot be secured due to a tendency of each unit in a plasma processing apparatus such as dry-etching unit, CVD unit, such inequality can be eliminated by controlling the wafer temperature locally at an area where that tendency occurs.

As the electrostatic chucking means which the present invention adopts, it is needless to say that any type, mono-pole type or bi-pole type, can be adopted.

Further, it is permissible to so construct that the rise in the wafer temperature can be executed by providing with a heating means such as heater or infrared ray irradiator for each chucking area on the wafer stage. Such a heating means is so constructed that the heating temperature can be adjusted independently for each chucking area by controlling current or voltage.

Although the above description states a case where helium is adopted as a heat medium, it is permissible to use other inert gas as long as it does not affect the wafer processing.

The present invention can be applied effectively to manufacturing field of the semiconductor device which needs to secure equality in flatness within the wafer surface.

1. A semiconductor manufacturing apparatus in which a wafer is held to a wafer stage by electrostatic chuck, wherein:
the wafer stage has a plurality of chucking areas capable of independently controlling chucking force; and
each of the chucking area comprises an electrostatic chucking means for applying electrostatic chucking force to the wafer; a temperature measuring means for measuring the temperature of the wafer; and a heat medium supply means for supplying heat medium between the wafer and the chucking area.

2. The semiconductor manufacturing apparatus according to claim 1 wherein the temperature measuring means is a fluorescent thermometer.

3. The semiconductor manufacturing apparatus according to claim 1 wherein the wafer stage is divided to a plurality of sections corresponding to the plurality of chucking areas.

4. The semiconductor manufacturing apparatus according to claim 1 wherein the wafer stage is divided into a plurality of sections corresponding to the plural chucking areas, each of the sectioned chucking areas has a plurality of smaller chucking areas and the electrostatic chucking means is provided in each of the smaller chucking areas.

5. The semiconductor manufacturing apparatus according to claim 1 wherein the wafer stage is not provided with any sections corresponding to the plurality of chucking areas but formed integrally.

6. A manufacturing method of semiconductor device having a step of executing a wafer processing in the conditions that the wafer is held to the wafer stage by electrostatic chuck, wherein
electrostatic chucking force of a wafer to a wafer stage is adjusted by a plurality of chucking area provided in the wafer stage based on a distribution of the temperatures of the wafer measured from the wafer stage side so as to suppress inequality based on the temperature distribution within the surface of the wafer during the wafer processing.

7. The manufacturing method of semiconductor device according to claim 6 wherein
the adjustment in electrostatic chucking force of the wafer to the wafer stage based on the distribution of temperature in the wafer is to increase/decrease the degree of chuck to the wafer stage of an inappropriate temperature area in the wafer which runs out of appropriate temperatures in the wafer processing by comparing with the degree of chuck to the wafer stage of an appropriate temperature area in the wafer.

8. The manufacturing method of semiconductor device according to claim 6 wherein
for restriction of inequality in the wafer processing based on the temperature distribution within the wafer surface, adjustment of supply of heat medium to between the wafer and the wafer stage is employed together with adjustment of the electrostatic chucking force.

9. A manufacturing method for semiconductor device having a step of executing a wafer processing in the conditions that the wafer is held to a wafer stage by electrostatic chuck, the manufacturing method comprising the steps of:
grasping a result of wafer fault after wafer processing corresponding to a wafer temperature; and
adjusting electrostatic chucking force of the wafer stage corresponding to a fault area of the wafer so as to change a wafer temperature corresponding to the wafer fault area, thereby suppressing inequality in the wafer processing based on the temperature distribution within the wafer surface.

10. The manufacturing method of semiconductor device according to claim 9 wherein the wafer processing is dry-etching.

11. The manufacturing method of semiconductor device according to claim 9 wherein the result of the wafer fault is a fault in processing dimension.

12. The manufacturing method of semiconductor device according to claim 9 wherein the result of the wafer fault is a fault in film thickness.

13. A manufacturing method of semiconductor device having a step of executing a wafer processing in the conditions that the wafer is held to a wafer stage by electrostatic chuck, wherein
supply amounts of heat medium supplied between the wafer and the wafer stage is adjusted based on the distribution of temperature of the wafer measured from the side of the wafer stage so as to suppress inequality in the wafer processing based on the temperature distribution within a wafer surface.

14. A wafer stage for holding a wafer by electrostatic chuck in manufacturing of semiconductor device, wherein
the wafer stage has a plurality of chucking areas; and
each of the chucking areas comprises an electrostatic chucking means for applying electrostatic chucking force to the wafer, a temperature measuring means for measuring the temperature of the wafer, and a heat medium supply means for supplying heat medium between the wafer and the chucking area.

15. The wafer stage according to claim 14 wherein the wafer stage is divided into a plurality of sections corresponding to the plurality of chucking areas.

16. The wafer stage according to claim 14 wherein the wafer stage is not provided with divided sections corresponding to the plurality of chucking areas but formed integrally.
